(19) United States
(12) Patent Application Publication
(10) Pub. No.: US 2015/0091048 A1
(43) Pub. Date: Apr. 2, 2015

(54) OPTICALLY-TRIGGERED SILICON CONTROLLED RECTIFIER AND METHOD OF FABRICATION OF THE SAME

(71) Applicant: SCIENTIFIC APPLICATIONS & RESEARCH ASSOCIATES, INC, Cypress, CA (US)

(72) Inventors: LELAND J. SPANGLER, MANITOU, CO (US); KENSALL D. WISE, ANN ARBOR, MI (US)

(21) Appl. No.: 14/500,378

(22) Filed: Sep. 29, 2014

Related U.S. Application Data
(60) Provisional application No. 61/883,789, filed on Sep. 27, 2013.

(51) Int. Cl. H01L 31/111; H01L 31/0232

(52) U.S. Cl. CPC H01L 31/1113; H01L 31/02327
USPC 257/117

(57) ABSTRACT

A device includes a semiconductor substrate having a plurality of doped layers forming first and second junctions. The semiconductor substrate includes a first surface and a second surface opposite the first surface. The device includes a plurality of waveguides defined by a plurality of glass inlaid channels defined within the first surface. Each of the plurality of glass inlaid channels extends through the second junction. The device includes a pattern of reflective elements associated with sidewalls of the plurality of glass inlaid channels to reflect light into the plurality of waveguides. A first electrically-conductive layer is disposed on the first surface and covers the plurality of glass inlaid channels.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

1. Technical Field

The present disclosure relates generally to solid state electronics. More particularly, the present invention relates to optically-triggered silicon controlled rectifiers and methods of fabrication of the same.

2. Discussion of Related Art

In general, a silicon controlled rectifier (SCR) is a four-layer P-N-P-N semiconductor device having three terminals. SCRs may be used as electronic switches in a variety of applications. The three terminals are “anode,” “cathode” and “gate.” In conventional electrically-triggered SCRs, when an appropriate voltage is applied between the cathode and anode and an appropriate current is applied to the gate, the device gets triggered or switched into a low resistance state and the device stays in that state, even if the triggering signal at the gate is removed. SCRs are primarily characterized by how much voltage they support in the “off-state,” how much current they can conduct in the “on-state,” and how fast they can switch or be triggered from the off-state to the on-state.

In order to be able to support a large off-state voltage, two characteristics are usually seen in SCRs. First, the depletion region, i.e., the N-type layer lying between the two P-type layers, is made with very high resistivity silicon and is made thick enough to be able to absorb a large depletion width without exceeding the maximum electric field that can exist in silicon. Furthermore, the exposed sidewalls of the device are typically shaped with a bevel or groove to decrease the electric field in those regions, thereby increasing the maximum off-state voltage the device can support without electric field breakdown.

Conventional SCRs use electrical current to switch the device. This current is injected into the P-type layer that adjoins the gate, and carriers diffuse to the depletion region where they induce an avalanche breakdown. In general, the speed of the device is set by the combination of the time it takes for injected carriers to diffuse from the gate contact to the depletion region plus the time it takes for the carriers to drift through the depletion region due to the electric field. Carrier diffusion is inherently slower that carrier drift and so conventional SCRs have speed limitations associated with the carrier diffusion time. To increase speed and increase off-state voltage, a variety of structures and geometries including cathode short structures, interdigitated and branched gate structures may be used all with the aim of reducing carrier diffusion time.

To ensure maximum current carrying capacity of SCRs in the on-state, it is desirable to minimize the gate area and maximize the cathode area and to have the overall structure conduct current in as uniform a manner as possible. On the other hand, enough area must be allocated for gate area so that enough carriers are injected to allow the device to turn-on as fast as possible without creating localized hot spots due to uneven turn-on. This tradeoff represents one of the significant design challenges in conventional SCR devices.

There is a need for improved fabrication techniques for SCR devices. It would be beneficial to have an SCR that is optically triggered.

### BRIEF SUMMARY

According to an aspect of the present disclosure, a device is provided that includes a semiconductor substrate having a plurality of doped layers forming first and second junctions. The semiconductor substrate includes a first surface and a second surface opposite the first surface. The device includes a plurality of waveguides defined by a plurality of glass inlaid channels defined within the first surface. Each of the plurality of glass inlaid channels extends through the second junction. The device includes a pattern of reflective elements associated with sidewalls of the plurality of glass inlaid channels to reflect light into the plurality of waveguides. A first electrically-conductive layer is disposed on the first surface and covers the plurality of glass inlaid channels.

### BRIEF DESCRIPTION OF THE DRAWINGS

Objects and features of the presently-disclosed optically-triggered silicon controlled rectifier (SCR) and method of fabrication of the same will become apparent to those of ordinary skill in the art when descriptions of various embodiments thereof are read with reference to the accompanying drawings, of which:

FIG. 1 is a diagrammatic representation of three types of processes for etching recesses in a silicon substrate;

FIGS. 2A-2D illustratively depict a process suitable for producing glass-in-silicon wafers in accordance with an embodiment of the present disclosure;

FIG. 3A is a cross-sectional view of an optically-triggered SCR structure fabricated using a glass reflow process in accordance with an embodiment of the present disclosure;

FIG. 3B is a cross-sectional view of an optically-triggered SCR structure fabricated using a glass reflow process in accordance with another embodiment of the present disclosure;

FIG. 4 is a diagrammatic representation of an optically-triggered SCR with the cathode partially removed, showing a glass inlay channel with patterned metal, in accordance with an embodiment of the present disclosure;

FIG. 5 is a cross-sectional view taken along the lines “5-5” of FIG. 4 in accordance with an embodiment of the present disclosure;

FIGS. 6A-6C are diagrammatic representations of glass inlay patterns in accordance with an embodiment of the present disclosure;

FIG. 7A is a cross-sectional view of packaging of an optically-triggered SCR in accordance with an embodiment of the present disclosure;

FIG. 7B is an enlarged cross-sectional view of the indicated area of detail of FIG. 7A in accordance with an embodiment of the present disclosure;

FIGS. 8 and 9 are diagrammatic representations of a method for coupling light into an optically-triggered SCR using fiber optic cable in accordance with an embodiment of the present disclosure; and

FIG. 10 is a flowchart illustrating a method of fabrication of an optically-triggered silicon controlled rectifier in accordance with an embodiment of the present disclosure.

### DETAILED DESCRIPTION

Hereinafter, embodiments of optically-triggered silicon controlled rectifiers and methods of fabrication of the same are described with reference to the accompanying drawings. Like reference numerals may refer to similar or identical elements throughout the description of the figures.

This description may use the phrases “an embodiment,” “in embodiments,” “in some embodiments,” or “other embodiments,” which may each refer to one or more of the same or different embodiments in accordance with the present disclosure.

Designs for optically-triggered SCRs can be contemplated in which light is directed in a direction perpendicular to the cathode surface. This creates the need to engineer a tradeoff in the use of the cathode area. In some instances, some portion of the cathode area may need to be covered with metal to allow electrical conduction through the cathode, and the other portion may need to be designed to allow the incident triggering light to penetrate into the silicon. In some instances, the package that houses the SCR incorporates copper cathode leads configured to also serve as heat sink structures, and the design of these structures may need to be compromised to allow for optical fibers or other optical paths to be created. For some medium- and low-power devices the cathode area-light illumination area tradeoff may not be an insurmountable tradeoff; however, for high-power devices this creates a significant challenge. Another factor associated with perpendicular or “vertical” illumination is that the light is only received next to the region that actually needs the light-generated carriers. This means that the light-generated carriers must diffuse to the depletion region that allows the SCR to switch. This carrier diffusion time imposes a speed limitation similar to that associated with the electrically-triggered SCRs. The small speed improvement of these types of optically-triggered SCRs comes from the fact that the carriers are generated in an area that is a bit closer to the junction.

These two limitations may be addressed by designs attempting to create devices that allow electron-hole pairs to be generated directly in the switching junction using “lateral” illumination. In order to achieve this, the sidewall of the junction must be exposed in some manner. In one approach, a conventional dicing saw is used to create a beveled trench. The beveled edge is illuminated normal to the surface of the SCR, and the light reflects off of the bevel and into the junction. This design suffers from the same tradeoff in the use of cathode area as does any other vertically illuminated device. Furthermore, the surface quality resulting from a sawing operation is not nearly sufficient to allow good optical qualities, so most of the incident optical power is lost through dispersion. Since dicing saws can only cut straight lines, there are limitations as to where the light is injected into the device by this approach.

In another approach, optical fibers may be stripped of their cladding and placed in grooves in silicon in such a manner that the light escapes from the fiber and illuminates the junction directly. This allows light to enter the junction laterally and is not limited as much by the cathode area. With this approach, a fiber optic cable must be placed in every groove and then secured in place in some manner, e.g., with a dispensed adhesive. This can be a highly labor-intensive manufacturing process, and the mechanical limitations of bending an optical fiber are a limit to where the fiber can be placed on the surface. This type of assembly is prone to significant manufacturing variation, which may lead to non-uniform triggering and may require that the switching speed and current density be reduced.

Various embodiments of the present disclosure provide a device and fabrication method for light waveguides in a silicon wafer that allow the light to be uniformly distributed over the surface of the wafer. Various embodiments of the present disclosure provide optically-triggered silicon controlled rectifiers (SCRs) configured to facilitate direct lateral illumination of the triggering junction with light to maximize switching speed. Embodiments of the presently-disclosed structures may be created in silicon and/or other materials to distribute the light throughout a particular device using microfabrication techniques. Embodiments of the presently-disclosed structures may have any suitable size, shape, density and location on the surface of a semiconductor substrate (e.g., SiC wafer) to direct the light in such a manner as to optimize the injection of carriers into the junction and/or to minimize lost cathode area. Optically-triggered SCRs built in accordance with fabrication methods of the present disclosure may have significantly reduced manufacturing costs because the presently-disclosed structures and/or devices can be built on silicon wafers, adopting technologies from integrated circuit (IC) manufacturing and batch fabrication techniques. This use of established “batch” processing to fabricate optically-triggered SCRs, similar to volume IC manufacturing processes, may eliminate many of the cost barriers that inhibit large scale production using other less proven technologies.

In accordance with embodiments of the present disclosure, process technologies suitable for the fabrication of silicon ICs and microelectromechanical systems (MEMS) devices may be used to create glass-inlaid channels that guide light directly to the junction that controls SCR triggering. In some embodiments, the process technology may include the ability to precisely etch fine features, grooves and channels into silicon. In addition, or alternatively, the process technology may include chemical-mechanical polishing (CMP) by which silicon wafers can be thinned and planarized with very high precision.

Referring now to FIG. 1, the precision etching of silicon can be categorized into isotropic, anisotropic and directional etching processes. Etching techniques, in particular as used to create cavities and recesses in silicon (e.g., recesses 12a, 12b and 12c) require the use of an etch mask 11 that exposes the area to be etched and protects, or masks, the area that is not desired to be etched. Isotropic etching is the removal of material equally in all directions resulting in a recess 12a having rounded sidewalls and undercutting of the etch mask 11. Anisotropic etching is the removal of material preferentially based on the crystal orientation of the substrate and the result is a recess 12b having 54.74° angled sidewalls when using <100> silicon. Directional etching involves removal of material straight down into the substrate 20 resulting in a recess 12c having vertical (or nearly vertical) sidewalls with aspect ratios of 40:1, or more.

In general, there are two classes of etching processes used in MEMS and IC fabrication: wet etching and dry etching. Wet etching is a process in which chemical solutions, or etchants, are used to dissolve areas of a silicon substrate that are unprotected by an etch mask. Two different types of wet etching are isotropic and anisotropic wet etching. Each of these etching techniques can be implemented in a number of different ways with different materials. The dry etching technology can be split in three separate classes called reactive ion etching (RIE), sputter etching, and vapor phase etching. RIE of silicon is independent of crystal planes, and therefore any shape can be fabricated, unlike anisotropic wet etching. Because ion bombardment is directional, RIE has anisotropic character, with reduced lateral etch rate and vertical (or nearly vertical) sidewalls. Deep reactive ion etching (DRIE) is an extension of RIE that enables high-rate etching of deep structures.

Chemical-mechanical polishing (CMP) involves the use of special equipment with customized slurries and pads to remove material from the surface of a wafer, thinning it and making the surface planar. CMP may be used to smooth the surface of inter-metal dielectric layers, which, in turn, allow many layers of metal interconnect on the surface of the device. CMP may additionally, or alternatively, be used to create the mirror smooth surface on the surface of silicon wafers.

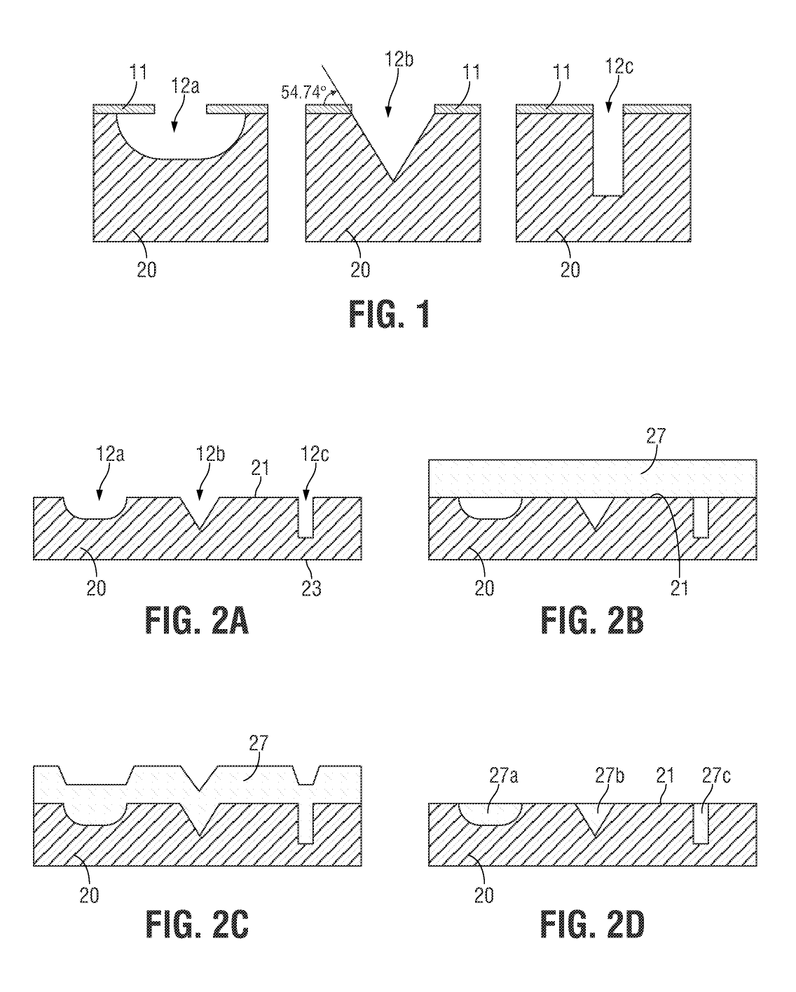

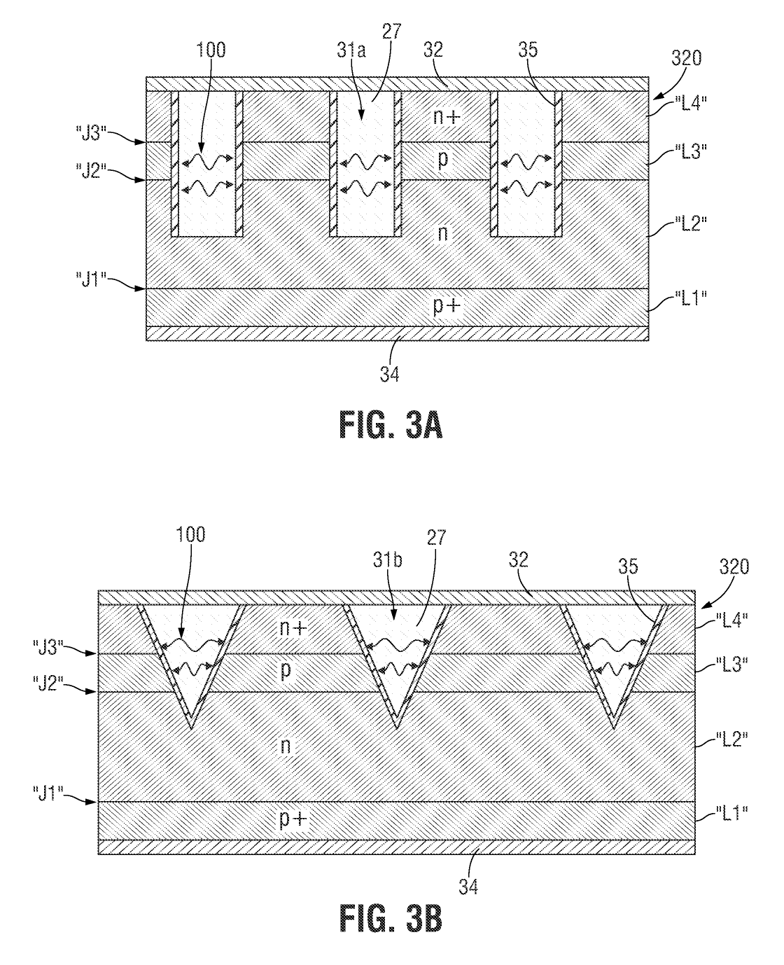

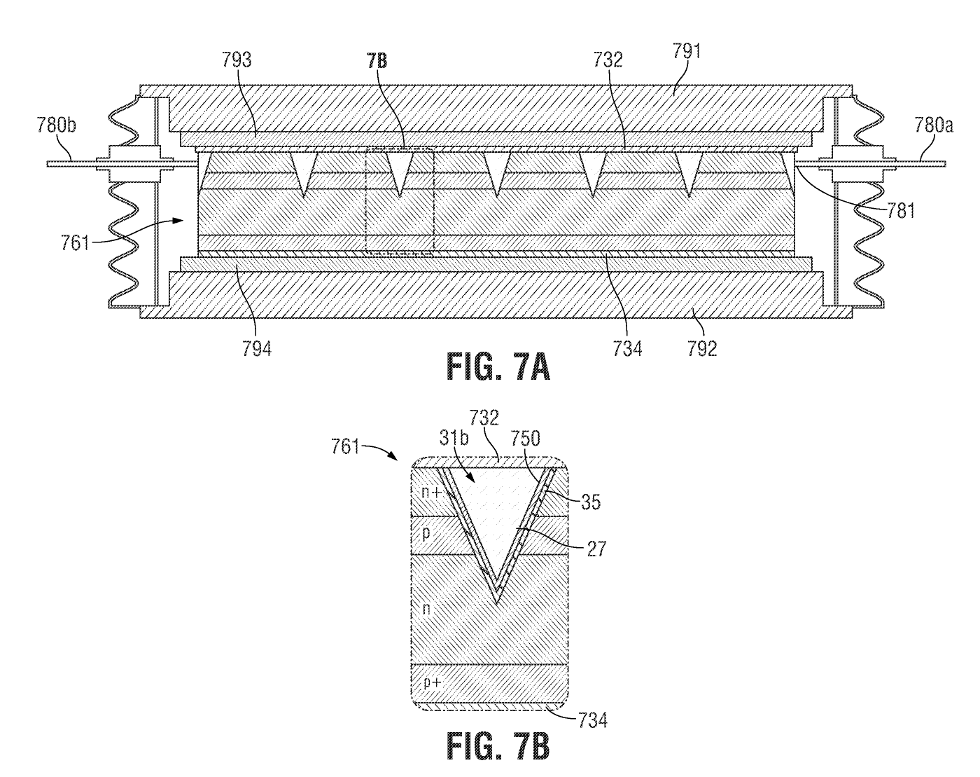

FIGS. 2A-2D show a glass inlay process that includes CMP. As described later in this description, other processing may be applied to the substrate 20 prior to the glass inlay process (e.g., cavity sidewalls may be coated with layers of dielectric as shown for example in FIGS. 3A and 3B, or with layers of dielectric and metal films as shown for example in FIG. 7B). Although a glass inlay process using anodic bonding is described below, it is to be understood that various other wafer bonding techniques, e.g., “fusion” or “direct” bonding, frit bonding, eutectic bonding, and the like, may also be used.

Referring to FIG. 2A, a substrate 20 having a first surface 21 (also referred to herein as an “upper surface”) and a second surface 23 (also referred to herein as a “lower surface”) is provided. One or more cavities (e.g., three cavities 12a, 12b and 12c) are formed into the upper surface 21 of the substrate 20, which may be a silicon wafer, to the desired depth and shape, e.g., using any of the three types of etching shown in FIG. 1, or stamping or otherwise forming cavities 12a, 12b and 12c.

As shown in FIG. 2B, a borosilicate glass wafer (e.g., Corning Code 7740 Pyrex™) is anodically bonded to the upper surface 21 of the substrate 20 in vacuum in such a manner that it seals a vacuum in the cavities 12a, 12b and 12c. Anodic bonding, a fabrication technique commonly used in MEMS fabrication, is a method of joining glass to silicon without the use of adhesives. In some embodiments, the bonding may be done at a temperature of about 350° C. and with an applied voltage of about 1000 VDC. Borosilicate glass approximately matches the thermal expansion coefficient of silicon in this temperature range, desirably minimizing stress as the wafer is cooled from the bonding temperature back down to room temperature.

After anodic bonding, the silicon-glass wafer sandwich is heated, e.g., to about 750° C., causing the glass to melt and as it does, the vacuum in the cavities 12a, 12b and 12c pulls the molten glass 27 into the cavities. FIG. 2C shows the glass 27 disposed within the cavities 12a, 12b and 12c in the substrate 20. Reliable and complete filling can be achieved for cavities as narrow as about 50 micrometers (μm) to about 100 μm, or narrower cavities. The glass-to-silicon seal in the cavities may be hermetic.

Etching, polishing and/or CMP may be used to remove the excess glass that did not inlay into the cavities, thereby exposing the upper surface 21, as shown for example in FIG. 2D. In some embodiments, the bottom surface 23 of the substrate 20 can remain unprocessed. As seen in FIG. 2D, after removal of the excess glass, the cavities 12a, 12b and 12c are filled with glass inlays 27a, 27b and 27c, respectively.

In some embodiments, the fabrication of an optically-triggered SCR may include the deposition of and patterning of layers of dielectric and/or metal films into the cavities in such a manner that the cavity sidewalls are coated prior to anodic wafer bonding. In embodiments wherein layers of dielectric and/or metal films are used, the upper surface 21 of the substrate 20 would still need to be exposed, e.g., through a surface polishing and/or etching process, to allow anodic bonding on the upper surface 21.

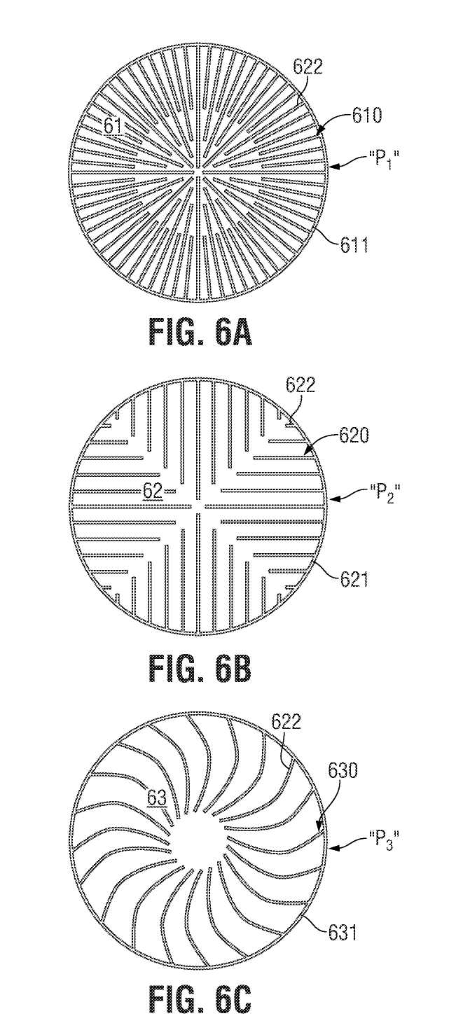

In various embodiments, the periphery of the presently-disclosed optically-triggered SCR is surrounded by glass, as described later in this description with reference to FIGS. 6A-6B. Creating single-crystal silicon structure and devices that are laterally surrounded by glass in accordance with the presently-disclosed fabrication methods allows for new types of high-speed optically-triggered SCRs such as the illustrative examples shown in FIGS. 3A and 3B. In FIGS. 3A and 3B, light that is carried by the glass 27 is denoted by the squiggly lines 100 within the cavities 31a and 31b, respectively. In the illustrative embodiments shown in FIGS. 3A and 3B, the glass-filled cavities are covered by an electrically-conductive layer 32 (e.g., cathode). An electrically-conductive layer 34 (e.g., anode) may be disposed on the bottom surface of the structure 320 (also referred to herein as “wafer 320”).

Various embodiments of the presently-disclosed optically-triggered SCR devices use configurations of inlaid glass as a waveguide to route the light 100 over the area of the SCR in such a manner as to optimize light penetration into the triggering junction while also maximizing the available cathode area. In accordance with the presently-disclosed fabrication methods, specific cross-sectional shapes of grooves and channels with inlaid glass as well as specific patterns of channels with inlaid glass are configured to distribute the light 100 over the surface of the device, e.g., in order to uniformly turn-on the device. Related to the shape and distribution of glass inlaid channels is the use of thin film layers on the sidewalls of the channels. These thin film layers can serve a variety of purposes. In some embodiments, the films may be transparent to the light that is used to trigger the device, in which case, the transparent films are used to provide an antireflective function through the proper use of index of refraction and film thickness. The thin films may be reflective to the triggering light to allow the light to be reflected back into the channel so it can propagate over a greater distance down the length of the channel, again with the objective of optimizing the uniformity of illumination to create a more uniform turn-on characteristic. It is contemplated that various configurations of the thin film layers can be used to tradeoff off-state voltage capability, speed, current carrying capability and fabrication cost.

A method of fabrication of an optically-triggered SCR in accordance with the present disclosure is described below. The method may be used to fabricate the structures shown in FIGS. 3A and 3B, for example. A silicon substrate (e.g., a SiC wafer) of appropriate thickness, doping type and crystal structure is diffused to form a four-layer P-N-P-N structure. The doped layers may include a first layer “L1” that may be an P-doped layer (e.g., a layer doped with a P-type dopant such as boron), a second layer “L2” that may be a N-doped layer (e.g., a layer doped with an n-type dopant such as phosphorus), a third layer “L3” that may be an P-doped layer, and a fourth layer “L4” that may be a N-doped layer. In one embodiment, the fourth layer “L4” is more heavily doped with the corresponding dopant (e.g., an N-type dopant) than the second layer “L2.” The first layer “L1” may be more heavily doped with the corresponding dopant (e.g., a P-type dopant) than the third layer “L3.”

In an embodiment, double- sided polished, very high resistivity (e.g., >500 ohm-cm), neutron-transmuted silicon is used. The P+ anode layer “L1” as well as the P+ gate layer “L3” are doped with boron to a very high concentration and the cathode layer “L4” is formed with a high concentration N+ diffusion. The wafer 320 is etched on the cathode side to create grooves or channels 31a and 31b through the triggering junction “J2” of the P-N-P-N stacks to expose junctions “J2” and “J3,” as shown for example in FIGS. 3A and 3B. The channels may be formed with a directional etch, an isotropic etch, or an anisotropic etch. If a directional etch is used, the slight scalloping of the sidewalls that may result might necessitate a polish or smoothing process, e.g., with a short isotropic plasma or wet etch (e.g., hydrofluoric, nitric, acetic). In some embodiments, a directional etch process is used to create surfaces that are normal to the direction of the light, which will decrease reflective loss since the light that is reflected off of the surface or interfaces will reflect back into the glass waveguide and be available for absorption at another location in the channel. In other embodiments, a sloped sidewall channel such as made with an anisotropic etchant will support higher voltages since the electric fields will be lower, as compared with a straight sidewall device. In some embodiments, a channel structure that is inverted such that the deeper part of the channel is wider than the upper portion, further “trapping” the light in the channel or focusing it primarily towards the triggering junction “J2,” may be used.

Embodiments of the presently-disclosed method of fabrication of an optically-triggered SCR may include the deposition of anti-reflective coatings on the sidewalls of the channels as well as the deposition and selective removal of light-reflecting materials to allow the light to be distributed uniformly throughout the active device area. The anti-reflective coatings and/or light-reflecting materials can be applied to the channels regardless of their shape or location. In some embodiments, the layers would be conformally deposited on the wafer so that the sidewalls of the channels are uniformly coated.

The anti-reflective coating of dielectric material may be selected to be of the appropriate thickness and index of refraction to optimize the coupling of light from the inlaid glass into the silicon. In some embodiments, this may be a quarter-wavelength (about 0.25 microns) thick layer of material with a refractive index that is the geometric average of the indexes of refraction of the two materials. In other embodiments, the wavelength may be about 1 micron and, given that silicon has an index of refraction of about 3.5 and glass has an index of refraction of about 1.45, a material with an index of refraction of about 2.25=(1.45×3.5)^{0.5} may be used Alternatively, another wavelength may be used.

In embodiments wherein the glass inlaid channels are completely surrounded by silicon and/or by reflective cathode metal (as described later in this description), the selection of an ideal coating is not necessary, since reflected light will just stay inside the glass and be available for absorption elsewhere in the channel. Silicon nitride, a commonly used material in silicon wafer fabrication, has an index of refraction of about 2 and may be suitable for this purpose. The Fresnel equations, which describe the reflection and refraction of incident light based on angles and indexes of refraction, may be used to provide a more comprehensive analysis of this feature.

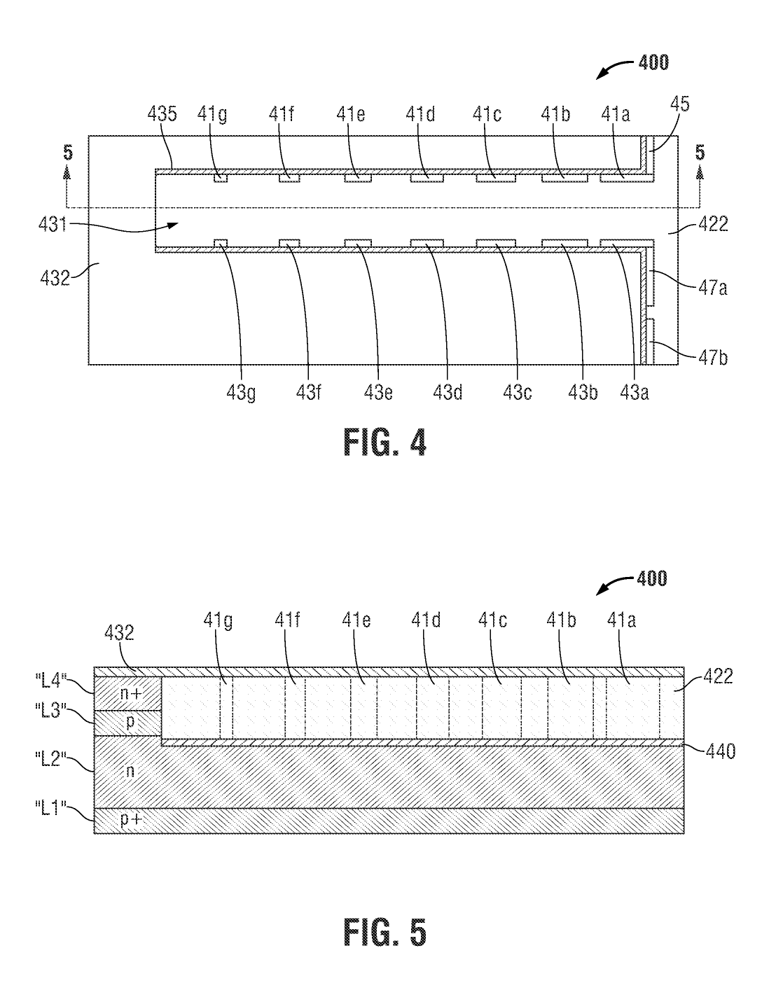

After the deposition of one or more dielectric layers into the channel, a conformal metal layer may be deposited and/or the sidewalls treated in a defined patterned manner that allows light absorption in desired locations, yet reflects the light back into the channel in other areas, as shown for example in FIGS. 4 and 5. This structure would allow the light absorption into the junction to be tailored over the surface of the device to help improve the uniformity of electron-hole pair generation and thus make the trigger signal more consistent over the device area. In the configuration shown in FIGS. 4 and 5, the exposed junction area near the light source (e.g., optical fiber 86a shown in FIG. 9) has fewer and smaller openings in the reflective layer (e.g., “narrow” spacing between the reflective elements 41a, 41b and 41c), and the exposed junction at the end of a channel and farthest from the light source has very little sidewall area covered with reflective material (e.g., “wide” spacing between the reflective elements 41e, 41f and 41g). In some embodiments, the reflective coating fully covers the bottom of the channel so that as much light is directed towards the switching junction as possible. In some embodiments, as shown for example in FIG. 4, the reflective elements are patterned such that the respective reflective elements progressively decrease in width as the distance of the respective reflective elements from the periphery of the device increases, and the spacing between the respective reflective elements increases as their distance from the periphery of the device increases.

Furthermore, the cathode metal can cover the entire top surface of the channel also helping to keep all of the light in the channel so it can be absorbed by the silicon and used for device triggering. This combination of thin films will allow the device to switch at the maximum speed possible by distributing the light uniformly over the switching junction.

FIGS. 4 and 5 show an optically-triggered SCR (shown generally as 400) in accordance with the present disclosure that includes a channel 431 defined in a P-N-P-N structure 400. The channel 431 may be formed by any suitable process, e.g., etching or stamping, and is filled with glass 422 (e.g., using the vacuum anodic bond and reflow process described with reference to FIGS. 2A-2D). As shown in FIGS. 4 and 5, the channel 431 is covered with a metal layer 432 that forms the cathode.

As shown in FIG. 4, a refraction matching layer 435 is deposited into the channel 431. A metal film is deposited and patterned into a plurality of reflective elements. In some embodiments as shown for example in FIG. 4, the metal film within the channel 431 is patterned into seven spaced-apart reflective elements 41a, 41b, 41c, 41d, 41e, 41f, 41g associated with one sidewall, and seven spaced-apart reflective elements 43a, 43b, 43c, 43d, 43e, 43f, 43g associated with the opposing sidewall. One or more additional reflective elements (e.g., reflective elements 45, 47a and 47b) may be associated within the periphery of the device. After deposition, these films must not be present on the cathode surface of the device when the glass is anodically bonded to the surface. Not only does the exposed silicon facilitate subsequent anodic bonding, but also the top surface must be electrically conductive to serve as the cathode of the device. The deposited films must also adhere well to the sidewalls of the silicon and the inlaid glass must “wet” to the deposited films to ensure proper optical performance and to reduce possible reliability issues associated with delamination.

After the cavities are formed and the sidewalls are coated with the desired films, the silicon wafer is then bonded to a glass (borosilicate) wafer in vacuum. After bonding, the silicon wafer with bonded glass is heated above the glass melting temperature, and the vacuum in the channels pulls the molten glass into them, filling the slots. The wafer is then cooled, and an etch and CMP process is used to remove the excess glass from the surface of the silicon and to polish the glass that remains in the channel thus creating a set of P-N-P-N silicon areas with channels of light directing glass interspersed over the surface. The anode and cathode sides of the device are then metallized to provide electrical contacts and to allow adequate heat sinking to the package. Since the top surface is planarized and made from solid materials, the metal can extend over the entire surface. This creates several benefits. First, it makes for a more effective cathode contact: since the entire surface is metalized, it can be used to transfer current to the package. Also, the metal over the glass channels helps to keep light in those channels until it passes through the anti-reflective coatings and into the silicon. This may significantly increase the optical efficiency of the device.

The presently-disclosed devices can dissipate large amounts of heat using relatively standard packaging and since there is no electrical gate contact, the entire cathode area can be optimized for maximum current carrying capability. By optimizing the layout of the channels (e.g., light distribution patterns shown in FIGS. 6A-6C), light can be distributed over the entire area of the wafer, thus generating electron-hole pairs where they are needed to allow the device to switch at very high speeds.

FIG. 6A shows an optically-triggered SCR 61 having a plurality of straight channels 610 filled with glass 622 extending inwardly from a glass edge portion 611 at the periphery “P₁” of the device. FIG. 6B shows an optically-triggered SCR 62 having a plurality of straight channels 620 filled with glass 622 extending from a glass edge portion 621 at the periphery “P₂” of the device. FIG. 6C shows an optically-triggered SCR 63 having a plurality of curvilinear channels 630 filled with glass 622 extending inwardly a glass edge portion 631 at the periphery “P₃” of the device.

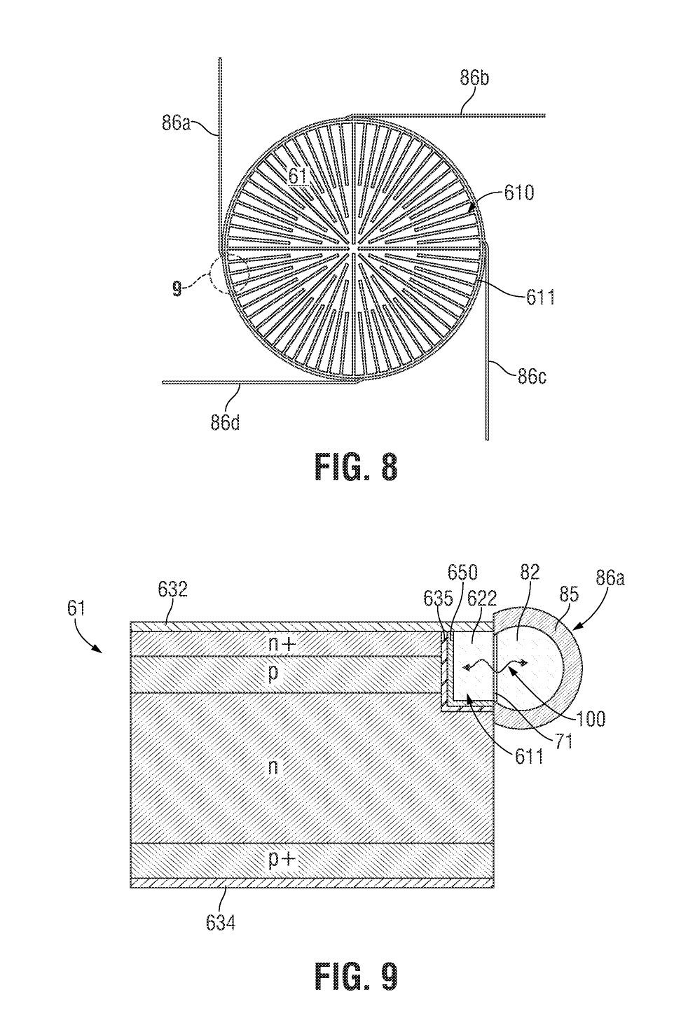

During fabrication, the channels must be laid out in a manner that allows them to be sealed during the anodic bonding process. After the wafers are fully fabricated, the individual optically-triggered SCR devices are cut from the wafer in such a manner that the periphery of each individual SCR device includes a circumference of glass around the periphery, as shown for example in FIGS. 6A-6C. This is to facilitate optical coupling, which is described with reference to FIGS. 8 and 9. In some embodiments, a cutting process may be used to remove the silicon that was used for sealing the channels, and the glass sidewalls of the wafer may then be polished to enhance subsequent light coupling. In accordance with various embodiments of the present disclosure, the fabricated devices would have a circular shape and thus several smaller devices could be fabricated in one wafer.

It is contemplated that the packaging of optically-triggered SCRs would leverage the similar technologies, materials and suppliers that are used in conventional SCRs, but the unique structure of the presently-disclosed optically-triggered SCRs will however bring some additional opportunities and challenges to the construction of the device. FIG. 7A shows packaging of an optically-triggered SCR in accordance with an embodiment of the present disclosure that includes a anode 792, a cathode 791, a first spacer 793, and a second spacer 794. In some embodiments, the first spacer 793 and/or the second spacer 794 may be made of Molybdenum.

FIG. 7A shows an optically-triggered SCR 761 having a first electrically-conductive layer 632 and a second electrically-conductive 634. As shown in FIG. 7A, the optically-triggered SCR 761 is provided with a housing having copper, anode 792 and cathode 791 contacts. The anode 792 and cathode 791 may be reduced in size and weight in the presently-disclosed optically-triggered SCR devices, because they do not have to accommodate a spring loaded electrical gate contact. Furthermore, the entire cathode region can be dedicated to electrical and thermal conduction, unlike conventional SCRs.

In one embodiment, with respect to coupling light from a fiber optic cable into the silicon device itself, fibers 780a and 780b would pass through a ceramic housing, e.g., using conventional Kovar feedthroughs. These feedthroughs, which are hermetic, are created during the fabrication of the ceramic housing. Once the optical fiber is inside the ceramic housing, the end would be stripped of its sheath and wrapped around the periphery of the device as shown schematically illustrated in FIG. 8. Any number of fibers could be used from one to many dozen depending on the amount of light in each fiber and the geometric limitations to bending the fiber. The multi-mode fibers would be side polished to expose the core (e.g., core 82 shown in FIG. 9) and since the core is made of glass as is the periphery (e.g., 622 shown in FIG. 9) of the device, both with an index of refraction about 1.45, the optical coupling into the periphery glass will be very high. An optically transparent, electrically insulative adhesive (e.g., material 71 shown in FIG. 9) may be used to secure the fibers to the device and provide the necessary optical coupling to maximize the number of photons that enter the glass regions of the device to trigger the SCR.

FIGS. 8 and 9 illustrate a method for coupling light into an optically-triggered SCR 61 in accordance with an embodiment of the present disclosure using fiber optic cable (e.g., four fibers 86a, 86b, 86c and 86d). The SCR 61 includes a P-N-P-N structure having a cathode 632 and an anode 634. In some embodiments, as shown for example in FIG. 9, the channel defined in the P-N-P-N structure at the edge of the device is provided with an index of refraction matching layer 635 and a reflective layer 650. The fiber (e.g., fiber 86a shown in FIG. 9) is side-polished, removing a portion of the sheath 85, and wrapped around the glass edge portion 611 at the periphery of the device. The portion 82 of the fiber 86a that is in contact with the periphery of the device has been side polished to allow contact to the exposed glass inlay 622. The side-polished optical fibers 86a, 86b, 86c and 86d may be attached to the glass edge portion 611 using any suitable optically transparent material 71 (e.g., an optically transparent, electrically insulative adhesive).

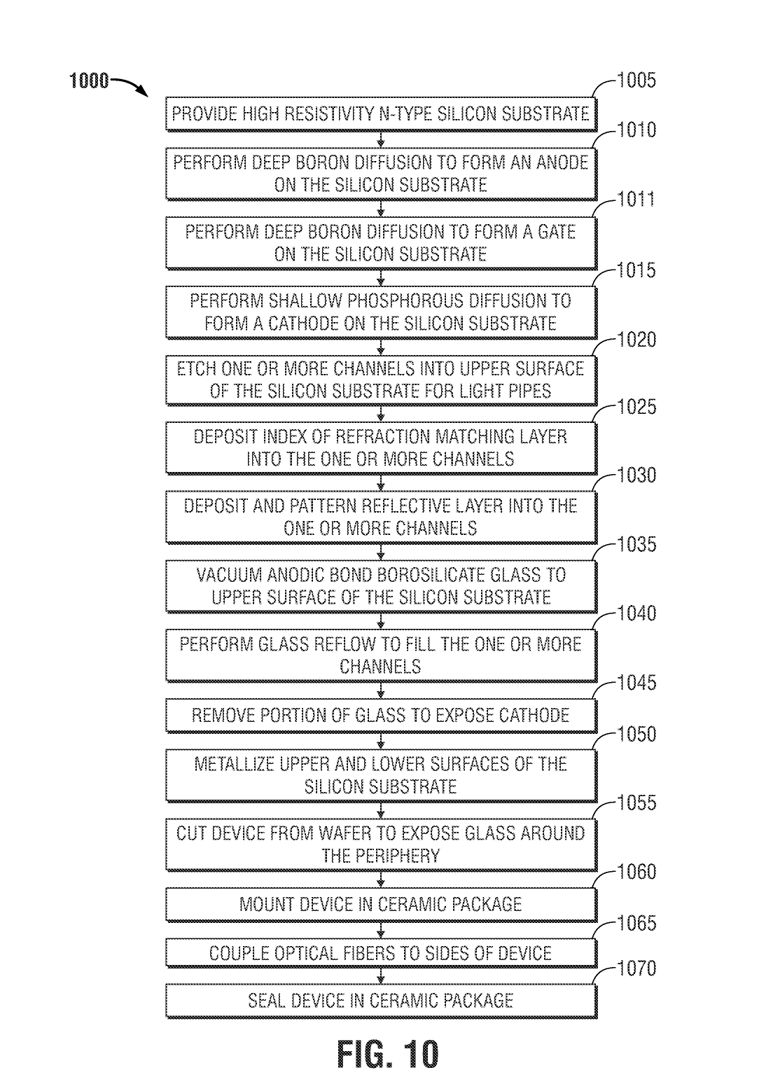

Hereinafter, a method of fabrication of an optically-triggered SCR in accordance with an embodiment of the present disclosure is described with reference to FIG. 10. It is to be understood that the functional blocks of the method provided herein (shown generally as 1000 in FIG. 10) may be performed in combination or in a different order than presented herein without departing from the scope of the disclosure.

In block 1005, a high resistivity N-type silicon substrate is provided.

In block 1010, deep boron diffusion is performed to form an anode on the silicon substrate.

In block 1011, deep boron diffusion is performed to form a gate on the silicon substrate.

In block 1015, shallow phosphorous diffusion is performed to form a cathode on the silicon substrate.

In block 1020, one or more channels are etched (or stamped or otherwise formed) into the upper surface of the silicon substrate for light pipes.

In block 1025, an index of refraction matching layer is deposited into the one or more channels.

In block 1030, a reflective layer is deposited into the one or more channels and patterned.

In block 1035, borosilicate glass is vacuum anodically bonded to the upper surface of the silicon substrate.

In block 1040, glass reflow is performed to fill the one or more channels.

In block 1045, a portion of the glass is removed to expose the cathode.

In block 1050, the upper and lower surfaces of the silicon substrate are metallized.

In block 1055, the device is cut from wafer to expose glass around the periphery.

In block 1060, the device is mounted in a ceramic package.

In block 1065, one or more optical fibers are coupled to the sides of the device.

In block 1070, the device is sealed in the ceramic package.

The above-described embodiments provide structures and/or devices configured to route light in glass inlaid channels over the surface of a semiconductor substrate (e.g., silicon wafer) in various patterns to distribute light over the substrate. The above-described methods of fabrication of optically-triggered SCRs include the creation of channels of a specified depth (e.g., about 0.5 microns to about 500 microns) in a silicon substrate in various configurations and using a vacuum anodic bond and reflow process to inlay the channels with glass.

The above-described devices include: devices with glass inlay channels for distributing light and having dielectric films in the inlay glass channels to reduce reflections of light from the glass as it passes into the silicon (e.g., anti-reflective coatings); devices with glass inlay channels for distributing light that has metal films on the bottom, sides, ends or tops of the channel to reflect the light and keep it in the channel; devices with the metal films patterned in such a manner as to allow light through in prescribed areas and reflected in the other areas; devices with glass inlay channels for distributing light that uses both dielectric anti-reflective films and metal films; and devices that couple light into the glass inlay channels by using side polishing optical fibers and attaching them to the periphery of the silicon at the glass inlay areas using an optically transparent means that couples the light from the fiber into the inlaid glass.

Although embodiments have been described in detail with reference to the accompanying drawings for the purpose of illustration and description, it is to be understood that the disclosed processes and apparatus are not to be construed as limited thereby. It will be apparent to those of ordinary skill in the art that various modifications to the foregoing embodiments may be made without departing from the scope of the disclosure.

What is claimed is:

1. A device, comprising:
a semiconductor substrate having a plurality of doped layers that form first and second junctions, the semiconductor substrate including a first surface and a second surface opposite the first surface;
a plurality of waveguides defined by a plurality of glass inlaid channels defined within the first surface, the plurality of glass inlaid channels extending through the second junction;
a pattern of reflective elements associated with sidewalls of the plurality of glass inlaid channels to reflect light into the plurality of waveguides; and
a first electrically-conductive layer disposed on the first surface and covering the plurality of glass inlaid channels.

2. The device of claim 1, wherein the first electrically-conductive layer forms a cathode contact.

3. The device of claim 2, further comprising a second electrically-conductive layer disposed on the second surface, the second electrically-conductive layer forming an anode contact.
